(19) United States
(12) Patent Application Publication
(10) Pub. No.: US 2025/0374800 A1
(43) Pub. Date: Dec. 4, 2025

(54) DISPLAY DEVICE

(71) Applicant: LG Display Co., Ltd., Seoul (KR)

(72) Inventors: Minkyu KIM, Paju-si (KR); Changheon KANG, Paju-si (KR)

(73) Assignee: LG Display Co., Ltd., Seoul (KR)

(21) Appl. No.: 19/220,698

(22) Filed: May 28, 2025

(30) Foreign Application Priority Data
May 29, 2024 (KR) 10-2024-0069780

(51) Int. Cl. H10K 59/80; H10K 59/122; H10K 59/40

(52) U.S. Cl. CPC H10K 59/8723; H10K 59/122; H10K 59/40

(57) ABSTRACT

A display device according to one embodiment of the present specification includes a display panel including a display area including a pixel and a non-display area located around the display area, and a mold disposed on a side surface of the display panel, wherein the display panel includes a substrate, at least one panel inorganic layer on the substrate, a light-emitting part on the at least one panel inorganic layer, a touch part including at least one touch inorganic layer on the light-emitting part and a touch electrode on the at least one touch inorganic layer, and a first touch organic layer on the touch part, and the substrate, the at least one panel inorganic layer, and the first touch organic layer come into contact with the mold.

### CROSS-REFERENCE TO RELATED APPLICATION

The present application claims priority to Korean Patent Application No. 10-2024-0069780, filed May 29, 2024, the entire contents of which is incorporated herein for all purposes by this reference.

### BACKGROUND

### Technical Field

The present specification relates to a display device, and more specifically, to a display device in which a narrow bezel is enabled and crack propagation can be prevented.

### Description of the Related Art

As the information society develops, various demands for display devices for displaying images are increasing, and various types of display devices such as liquid crystal display (LCD) devices and organic light-emitting diode (OLED) display devices are utilized.

A display device includes a plurality of pixels and a plurality of switching elements for driving and controlling the pixels.

### BRIEF SUMMARY

The disclosed display device enhances edge durability and minimizes defect risks through a novel structure in which the side surfaces of the substrate, panel inorganic layers, touch inorganic layers, and touch organic layers are aligned and come into contact with a surrounding mold. This alignment secures rigidity at the trimmed edges, strengthens bonding between layers, and helps prevent film lifting or peeling, which is important for enabling a narrow bezel design. Additionally, first and second stop holes are formed in the panel and touch inorganic layers, respectively, and are filled with a clad part and touch organic layer to trap residual films and act as crack stoppers, thereby preventing crack propagation and foreign substance defects.

The device further includes a clad part in the non-display area, composed of protective and spacer layers, which reinforces structural integrity and interfaces with the stop holes. In the bending region, a cover layer positions link lines along the neutral plane to protect them from mechanical stress during folding. Together, these features improve reliability, manufacturability, and mechanical robustness of the display panel.

Embodiments of the present specification are directed to providing a display device having a narrow bezel.

Embodiments of the present specification are also directed to providing a display device in which rigidity of a trim line (or an edge) is secured.

Embodiments of the present specification are also directed to providing a display device in which a film lifting or peeling between films is improved by removing an organic film step on a clad part.

Embodiments of the present specification are also directed to providing a display device that has relieved stress between films and is robust to film lifting by reinforcing bonding strength between films.

Embodiments of the present specification are also directed to providing a display device that is robust to crack propagation.

Technical benefits of the present specification are not limited to the above-described benefits, and other benefits may be inferred from the following embodiments.

According to one embodiment, there is provided a display device including a display panel including a display area including a pixel and a non-display area located around the display area, and a mold disposed on a side surface of the display panel, wherein the display panel includes a substrate, at least one panel inorganic layer on the substrate, a light-emitting part on the at least one panel inorganic layer, a touch part including at least one touch inorganic layer on the light-emitting part and a touch electrode on the at least one touch inorganic layer, and a first touch organic layer on the touch part, and the substrate, the at least one panel inorganic layer, and the first touch organic layer come into direct contact with the mold.

According to another embodiment, there is provided a display device including a substrate including a display area including a pixel and a non-display area located around the display area, at least one panel inorganic layer on the substrate, a protective layer on the at least one panel inorganic layer, a light-emitting part including an anode electrode on the protective layer, an organic layer on the anode electrode, and a cathode electrode on the organic layer, a bank covering an edge of the anode electrode and disposed between the anode electrode and the organic layer, and a clad part including a spacer between the bank and the organic layer, located in the non-display area, and formed of the protective layer, the bank, or the spacer, wherein the at least one panel inorganic layer includes a first stop hole that overlaps the clad part and passes through in a thickness direction of the display panel, and the clad part fills the first stop hole and comes into direct contact with the substrate.

Detailed matters of other embodiments are included in detailed description and accompanying drawings.

### BRIEF DESCRIPTION OF THE SEVERAL VIEWS OF THE DRAWINGS

FIG. 1 is a plan view of a display device according to one embodiment.

FIG. 2 is a cross-sectional view illustrating a bent state of a display panel according to FIG. 1.

FIG. 3 is a plan view illustrating a bent state of the display device according to FIG. 1.

FIG. 4 is a cross-sectional view along line A-A′ in FIG. 3.

FIG. 5 is a cross-sectional view along line B-B′ in FIG. 3.

FIG. 6 is an enlarged cross-sectional view of area Q1 in FIG. 5.

FIG. 7 is a cross-sectional view along line C-C′ in FIG. 3.

FIG. 8 is an enlarged cross-sectional view of area Q2 in FIG. 7.

FIG. 9 is a cross-sectional view of a display device according to a comparative example.

FIG. 10 is a cross-sectional view of a display device according to another embodiment.

FIG. 11 is a schematic view illustrating cracks formed at an end portion of the display panel and blocked through a first stop hole and a second stop hole.

FIG. 12 is a schematic view illustrating a process of removing a trimming part of the display device according to FIG. 10.

FIG. 13 is a cross-sectional view of a display device according to still another embodiment.

FIG. 14 is an enlarged cross-sectional view of area Q3 in FIG. 13.

### DETAILED DESCRIPTION

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the specification, when a first component (or an area, a layer, a portion, etc.) is described as “on,” “connected,” or “coupled to” a second component, it means that the first component may be directly connected/coupled to the second component or a third component may be disposed therebetween.

To elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” and the like can be used to easily describe the correlation of one element or components with another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification may be coupled or combined partially or entirely, and various technological interworking and driving are possible, and the embodiments may be implemented independently of each other or implemented together in an associated relationship.

Hereinafter, a display device of the present specification will be described with reference to the accompanying drawings and embodiments as follows.

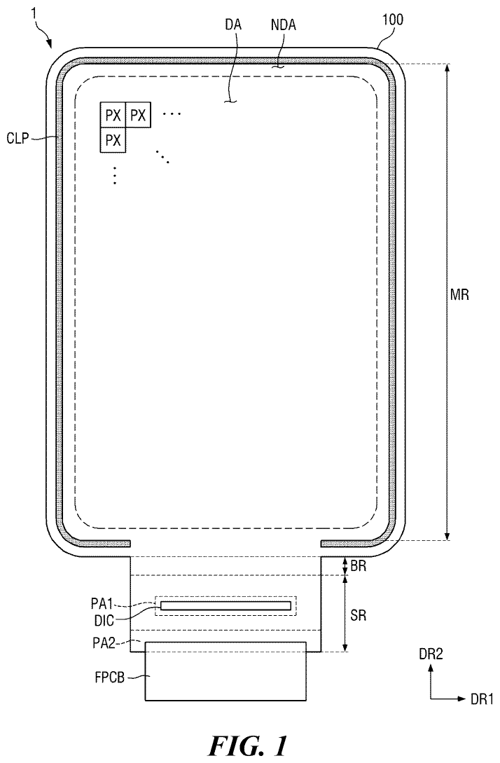

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments of the present specification are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiment should be understood as indicating relative directions, and the embodiment is not limited to the described directions.

The display area DA may include short sides extending in a first direction DR1 and long sides extending in a second direction DR2. The non-display area NDA may surround the display area DA. The non-display area NDA may be disposed at one side and the other side of the display area DA in the first direction DR1 and one side and the other side of the display area DA in the second direction DR2.

The non-display area NDA located at the other side of the display area DA in the second direction DR2 may extend further from a central portion of the other side in the second direction DR2 toward the other side in the second direction DR2 of the display area DA. A width of the non-display area NDA in the first direction DR1 further extending from the central portion of the other side in the second direction DR2 toward the other side in the second direction DR2 of the display area DA may be smaller than a width of the non-display area NDA in the first direction DR1 adjacent to the other side of the display area DA in the second direction DR2.

The display device 1 may include a main region MR, a sub-region SR, and a bending region BR between the main region MR and the sub-region SR. The display area DA and the non-display area NDA surrounding four sides of the display area DA constitute the main region MR, and a portion extending from the central portion of the other side in the second direction DR2 toward the other side in the second direction DR2 of the display area DA may constitute the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driving unit DIC and the printed circuit board FPCB may be disposed in the first pad area PA1 and the second pad area PA2. The data driving unit DIC may be configured, for example, in the form of a driving chip (IC), but is not limited thereto. In one embodiment, an example in which the data driving unit DIC is disposed by a method of a chip on plastic that is directly mounted on the display panel 100 is described, but the embodiments of the present specification are not limited thereto, and the data driving unit DIC may be disposed by a method of a chip on glass or a chip on film.

The display panel 100 according to one embodiment may further include a clad part CLP. The clad part CLP may be disposed on the main region MR and may not be disposed on the bending region BR and the sub region SR. The clad part CLP may be disposed on the non-display area NDA. The clad part CLP may be disposed in the non-display area NDA of one side of the display area DA in the first direction DR1, the non-display area NDA of the other side in the first direction DR1, and the non-display area NDA of one side of the display area DA in the second direction DR2. The clad parts CLPs disposed in the non-display area NDA of one side of the display area DA in the first direction DR1, the non-display area NDA of the other side in the first direction DR1, and the non-display area NDA of one side of the display area DA in the second direction DR2 may be formed integrally, but the embodiments of the present specification are not limited thereto. The clad part CLP may also be disposed to partially extend to the non-display area NDA of the other side of the display area DA in the second direction DR2, but the embodiments of the present specification are not limited thereto.

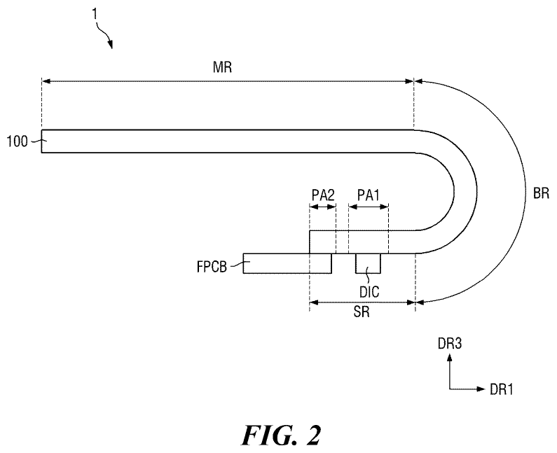

FIG. 2 is a cross-sectional view illustrating a bent state of a display panel according to FIG. 1.

Referring to FIG. 2, the bending region BR of the display panel 100 of the display device 1 according to one embodiment may be bent in a thickness direction of the display panel 100 (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

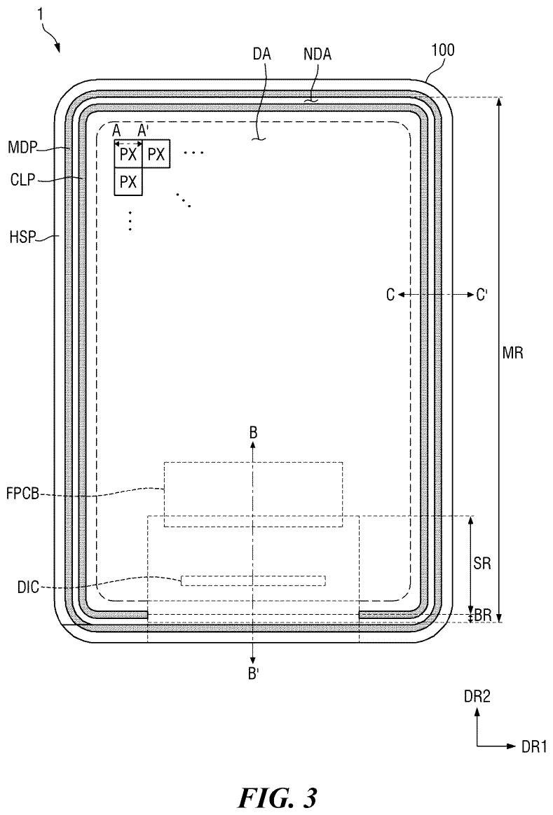

FIG. 3 is a plan view illustrating a bent state of the display device according to FIG. 1.

Referring to FIG. 3, the display device 1 may further include a mold MDP and a housing HSP.

The bending region BR of the display panel 100 may be bent so that the sub-region SR may overlap the main region MR. The printed circuit board FPCB and the data driving unit DIC may each overlap the main region MR.

The mold MDP may be disposed outside the display panel 100. The mold MDP may be disposed along an edge of the bent display panel 100. The mold MDP may come into direct contact with side surfaces of the bent display panel 100. The mold MDP may include an organic material. The mold MDP may include an organic material that repeatedly shrinks and expands according to heat. The mold MDP may be for example used to support the display panel 100.

The housing HSP may be disposed outside the display panel 100 and the mold MDP. The housing HSP may be disposed along an edge of the mold MDP.

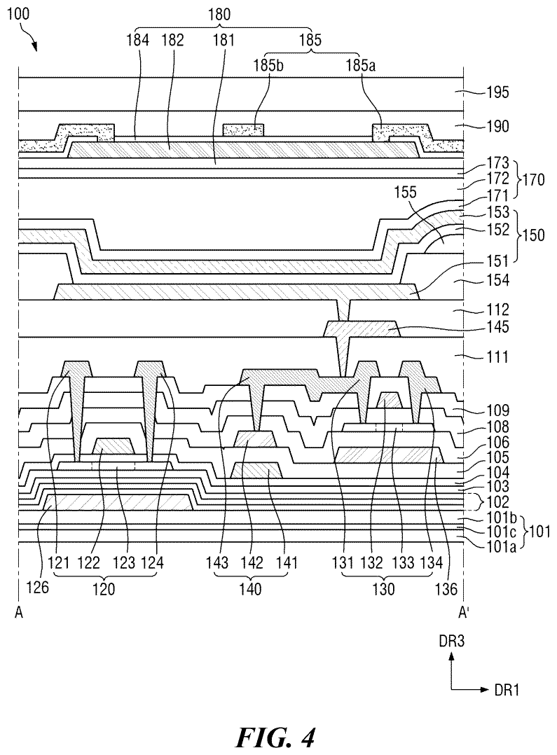

FIG. 4 is a cross-sectional view along line A-A′ in FIG. 3.

Referring to FIG. 4, the display panel 100 may include a substrate 101, a first thin film transistor 120, a second thin film transistor 130, a light-emitting part 150, an encapsulation part 170, a touch part 180, touch organic layers 190 and 195. The display panel 100 may include at least one panel inorganic layer and at least one touch inorganic layer between the substrate 101 and the touch organic layer 190. The at least one panel inorganic layer may include at least one of a buffer layer 102, a first insulating layer 103, a second insulating layer 104, a third insulating layer 105, a fourth insulating layer 106, a fifth insulating layer 108, and a sixth insulating layer 109, and the at least one touch inorganic layer may include at least one of a touch buffer layer 181 and an insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic material between the first substrate portion 101a and the second substrate portion 101b, but the embodiments of the present specification are not limited thereto.

A first light-shielding layer 126 may be disposed on the substrate 101. The first light-shielding layer 126 can prevent light from transmitting to a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

The buffer layer 102 may be disposed on the first light-shielding layer 126. The buffer layer 102 can minimize or delay the diffusion of moisture or oxygen penetrating the substrate 101. The buffer layer 102 may be formed by alternately stacking silicon nitride (SiNx) and silicon oxide (SiOx) at least once, but the embodiments of the present specification are not limited thereto.

The first insulating layer 103 may be disposed on the buffer layer 102. The first insulating layer 103 can prevent a short circuit between a component of the first thin film transistor 120 and the first light-shielding layer 126. The first insulating layer 103 may be formed of the same material as the buffer layer 102, but the embodiments of the present specification are not limited thereto. For example, the first insulating layer 103 may be formed of an inorganic material, such as silicon nitride (SiNx) or silicon oxide (SiOx), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The first gate electrode 122 may be disposed along with a gate line.

The third insulating layer 105 may be disposed on the first gate electrode 122. The third insulating layer 105 may be formed of the same material as the first insulating layer 103 or the second insulating layer 104, but the embodiments of the present specification are not limited thereto.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present specification are not limited thereto.

A storage electrode 140 may be disposed to be spaced apart from the first thin film transistor 120. The storage electrode 140 may include a first storage electrode 141, a second storage electrode 142, and a third storage electrode 143.

The first storage electrode 141 may be formed of the same material as the first gate electrode 122 and disposed on the same layer as the first gate electrode 122, but the embodiments of the present specification are not limited thereto.

The third insulating layer 105 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent light from traveling to the second semiconductor layer 133 similar to the first light-shielding layer 126, thereby extending the life of the second thin film transistor 130. For example, the second semiconductor layer 133 may be disposed to overlap the second light-shielding layer 136.

The fourth insulating layer 106 may be disposed on the second light-shielding layer 136. The fourth insulating layer 106 may be formed of the same material as the first insulating layer 103, the second insulating layer 104, or the third insulating layer 105, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

The fifth insulating layer 108 may be disposed on the second semiconductor layer 133. The fifth insulating layer 108 may be formed of the same material as the first insulating layer 103, the second insulating layer 104, the third insulating layer 105, or the fourth insulating layer 106, but the embodiments of the present specification are not limited thereto.

A second gate electrode 132 may be disposed on the fifth insulating layer 108.

The second gate electrode 132 may be formed of the same material as the first gate electrode 122. For example, the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto.

The sixth insulating layer 109 may be disposed on the second gate electrode 132. The sixth insulating layer 109 may be formed of the same material as the first insulating layer 103, the second insulating layer 104, the third insulating layer 105, the fourth insulating layer 106, or the fifth insulating layer 108, but the embodiments of the present specification are not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as the first source electrode 121 and the first drain electrode 124 and disposed on the same layer as the first source electrode 121 and the first drain electrode 124, but the embodiments of the present specification are not limited thereto. For example, the third storage electrode 143, the second source electrode 131, and the second drain electrode 134 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto. For example, the third storage electrode 143 and the second source electrode 131 may be directly connected, but the embodiments of the present specification are not limited thereto.

The first thin film transistor 120 may be a driving transistor, and the second thin film transistor 130 may be a switching transistor, but the embodiments of the present specification are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material containing an acrylic resin, an epoxy resin, a phenolic resin, a polyamide resin, or a polyimide resin, but the embodiments of the present specification are not limited thereto.

A second protective layer 112 may be disposed on the first protective layer 111. The second protective layer 112 may be formed of the same material as the first protective layer 111, but the embodiments of the present specification are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present specification are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting part 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but the embodiments of the present specification are not limited thereto. The anode electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC (Ag—Pd—Cu) alloy and may be formed of a single layer or multiple layers, but the embodiments of the present specification are not limited thereto.

The organic layer 152 may be disposed on the anode electrode 151. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include the organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto.

The cathode electrode 153 may be disposed on the organic layer 152. The cathode electrode 153 may be a transparent electrode that transmits light, but the embodiments of the present specification are not limited thereto. For example, the cathode electrode 153 may include a transparent conductive material, such as indium tin oxide (ITO) or indium zinc oxide (IZO), or a metal that transmits visible light, but the embodiments of the present specification are not limited thereto.

A bank 154 may be disposed to expose the anode electrode 151. The bank 154 may define an opening (or a light-emitting area) of a sub-pixel and may be disposed to cover an edge portion (or a border portion) of the anode electrode 151. Each sub-pixel may include a red light-emitting area, a green light-emitting area, and a blue light-emitting area. For example, the sub-pixel may be a pixel, but is not limited by the term. The bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be a black bank. When the bank 154 is formed of a material containing black pigment or black dye, it is possible to shield external light or light reflected from the outside, thereby further increasing the luminance of the display device. A spacer 155 may be further disposed on the bank 154. The spacer may be formed of the same material as the bank 154, but the embodiments of the present specification are not limited thereto.

The encapsulation part 170 may be disposed above the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present specification are not limited thereto.

The touch buffer layer 181 may be disposed on the encapsulation part 170. For example, the touch buffer layer 181 may be disposed on the third encapsulation layer 173. The touch buffer layer 181 may be formed of the same material as the buffer layer 102, but the embodiments of the present specification are not limited thereto. The insulating layer 184 may be disposed on the touch buffer layer 181. The insulating layer 184 can prevent a short circuit between touch electrodes. The insulating layer 184 may be made of silicon oxide (SiOx), silicon nitride (SiNx), or multiple layers thereof, but the embodiments of the present specification are not limited thereto. A first touch electrode 185 may be disposed on the insulating layer 184. The first touch electrode 185 may include a touch electrode 185a extending in a first direction and a touch electrode 185b extending in a second direction that differs from the first direction.

A second touch electrode 182 may be disposed between the touch buffer layer 181 and the insulating layer 184.

The second touch electrode 182 may be electrically connected to the touch electrode 185a through a contact hole formed in the insulating layer 184. For example, the touch electrode 185a and the second touch electrode 182 may extend in the first direction.

The first touch electrode 185 and the second touch electrode 182 may include a metallic material. For example, the first touch electrode 185 and the second touch electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

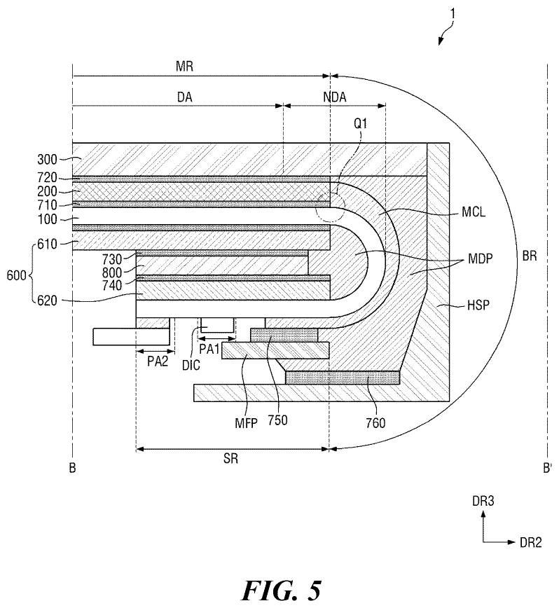

FIG. 5 is a cross-sectional view along line B-B′ in FIG. 3.

Referring to FIGS. 4 and 5, the display device 1 may include the display panel 100, a polarization layer 200, a cover layer 300, a backplate layer 600, a plate layer 800, bonding layers 710, 720, 730, 740, and 750, a cover layer MCL, a mold MDP, a mold frame MFP, and a housing HSP. The mold frame MFP may be used, for example, for assembling and fixing of the display panel 100, for structural supporting for the display panel 100, for integrated assembling of the display panel 100, for dust and shock proofing of the display panel 100, and the like. The mold frame MFP may for example be made of a high strength engineering plastic, such as PC/ABS.

The bending region BR of the display panel 100 may have a curved shape and may be bent in the thickness direction. The main region MR and the sub-region SR of the display panel 100 may overlap each other.

The polarization layer 200 may be disposed on the main region MR of the display panel 100. The polarization layer 200 may polarize light emitted from the display panel 100 at a polarization angle. The polarization layer 200 may emit light polarized at the polarization angle to the outside. The polarization layer 200 may include a function of blocking the reflection of light excluding the light polarized at the polarization angle among external light. The polarization layer 200 may include a first phase retardation layer, a second phase retardation layer on the first phase retardation layer, and a polarization layer on the second phase retardation layer. In FIG. 5, an example in which the polarization layer 200 and the display panel 100 are separated is illustrated, but the embodiments of the present specification are not limited thereto, and the polarization layer 200 may be included in the display panel 100.

A cover layer 300 may be disposed on the polarization layer 200. The cover layer 300 may be formed of a glass material including glass, quartz, etc., but the embodiments of the present specification are not limited thereto, and the cover layer 300 may be formed of a plastic material. The cover layer 300 may be disposed above the display panel 100 to protect members disposed under the cover layer 300 from the outside. The cover layer 300 may be a cover layer formed by chemical reinforcement, but the embodiments of the present specification are not limited thereto. The cover layer 300 may be a cover window, a window cover, or a cover member, but the embodiments of the present specification are not limited thereto.

The cover layer 300 can protect the members disposed under the cover layer 300 from the outside, but as described above, since the cover layer 300 is formed of a glass material, the cover layer 300 can be damaged by an external force to create glass fragments. The glass fragments may shatter to the outside of the display device 1. According to the embodiment of the present specification, to prevent the shattering of the glass fragments due to the damage to the cover layer 300 or increase the durability of the cover layer 300, the display device 1 may further include at least one additional layer on the cover layer 300. For example, the display device 1 may further include a film layer or a coating layer on the cover layer 300, but the embodiments of the present specification are not limited thereto.

A side surface of the cover layer 300 may protrude outward more than a side surface of the display panel 100. For example, the side surface of the cover layer 300 may protrude outward more than the end portion of the bending region BR of the display panel 100, but the embodiments of the present specification are not limited thereto.

The backplate layer 600 may be disposed under the display panel 100. The backplate layer 600 may be disposed under the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but the embodiments of the present specification are is not limited thereto. The backplate layer 600 can maintain a constant curvature of the display panel 100 when the display device 1 is folded and suppress wrinkles occurring on an upper surface of the display panel 100.

The backplate layer 600 may include a first backplate layer 610 on the main region MR and a second backplate layer 620 on the sub-region SR. The first backplate layer 610 may be disposed between the main region MR of the display panel 100 and the plate layer 800, and the second backplate layer 620 may be disposed between the sub-region SR of the display panel 100 and the plate layer 800. The backplate layer 600 may not be disposed on the bending region BR.

The plate layer 800 may be disposed between the first backplate layer 610 and the second backplate layer 620. The plate layer 800 may include a metal. For example, the plate layer 800 may include stainless steel, but the embodiments of the present specification are not limited thereto.

Additional bonding layers may be disposed between the above members 100, 200, 300, 600, and 800. The bonding layers may include a first bonding layer 710, a second bonding layer 720, a third bonding layer 730, a fourth bonding layer 740, a fifth bonding layer 750, and a sixth bonding layer 760.

The first bonding layer 710 may be disposed between the display panel 100 and the polarization layer 200. The first bonding layer 710 may connect or couple the display panel 100 to the polarization layer 200.

The second bonding layer 720 may be disposed between the polarization layer 200 and the cover layer 300. The second bonding layer 720 may connect or couple the polarization layer 200 to the cover layer 300.

The third bonding layer 730 may be disposed between the first backplate layer 610 and the plate layer 800. The third bonding layer 730 may connect or couple the first backplate layer 610 to the plate layer 800.

The fourth bonding layer 740 may be disposed between the second plate layer 620 and the plate layer 800. The fourth bonding layer 740 may connect or couple the second backplate layer 620 to the plate layer 800.

The fifth bonding layer 750 may be disposed between the mold frame MFP and the cover layer MCL. The fifth bonding layer 750 may connect or couple the mold frame MFP to the cover layer MCL.

The sixth bonding layer 760 may be disposed between the mold MDP and the housing HSP. The sixth bonding layer 760 may connect or couple the mold MDP to the housing HSP.

The first bonding layer 710 and the second bonding layer 720 may each include a transparent adhesive, but the embodiments of the present specification are not limited thereto. For example, the transparent adhesive may be a transparent resin (OCR) or a transparent adhesive (OCA), but the embodiments of the present specification are not limited thereto. The third bonding layer 730, the fourth bonding layer 740, the fifth bonding layer 750, and the sixth bonding layer 760 may each include a pressure sensitive adhesive (PSA), but the embodiments of the present specification are not limited thereto.

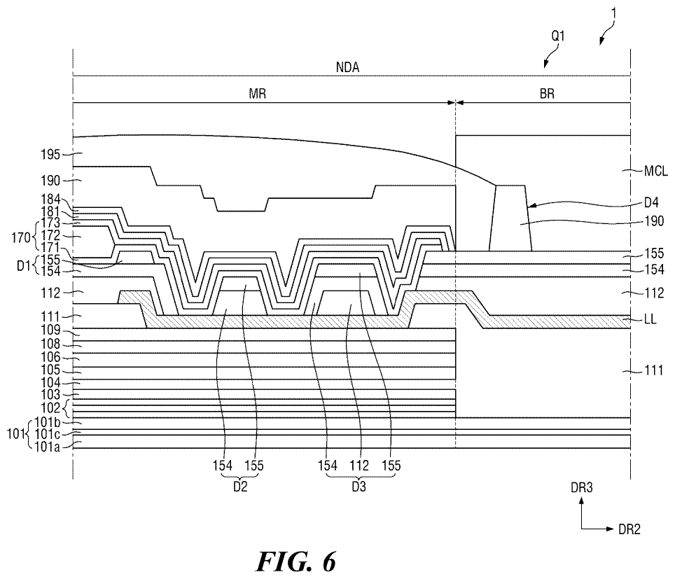

The cover layer MCL may be disposed on one surface of the bending region BR of the display panel 100. The cover layer MCL may include a plastic material and may be coated on the one surface of the bending region BR of the display panel 100 to cover the bending region BR of the display panel 100. A link line (e.g., see LL of FIG. 6) may be disposed on the bending region BR. The cover layer MCL can protect the link line LL from an external impact and prevent moisture from penetrating the link line LL. In addition, the cover layer MCL may serve to locate the link line LL on a neutral plane when the bending region BR of the display panel 100 is bent in a curved shape having a constant radius of curvature. Since the neutral plane in which a tensile force and a compressive force are zero is formed in the bending region BR, and the link line LL is located on the neutral plane, when the display panel 100 is bent, the link line LL may receive bending stress of zero, and thus may be bent without damaged by the bending stress.

The cover layer MCL may come into contact with side surfaces of the polarization layer 200 and the first bonding layer 710. A part of the cover layer MCL may extend to the sub-region SR. On the sub-region SR, the cover layer MCL may be coupled to the mold frame MFP through the fifth bonding layer 750.

The data driving unit DIC may be disposed in the first pad area PA1 of the sub-region SR, and the printed circuit board FPCB may be disposed in the second pad area PA2. The printed circuit board FPCB may be electrically connected to pads on the display panel 100 through an anisotropic conductive film ACF. The cover layer MCL may not overlap the data driving unit DIC, but the embodiments of the present specification are not limited thereto.

The mold frame MFP may be disposed under the cover layer MCL. The mold frame MFP and the cover layer MCL may be bonded through the fifth bonding layer 750.

The mold MDP may be disposed on the cover layer MCL. The mold MDP may cover an outer surface of the bending region BR of the display panel 100. For example, the mold MDP may come into direct contact with the cover layer MCL, a lower surface of the cover layer 300, a side surface of the fifth bonding layer 750, and an upper surface, side surface, and lower surface of the mold frame MFP. The mold MDP may also come into contact with an inner surface of the housing HSP. The mold MDP may also be disposed inside the bending region BR. The mold MDP may come into contact with an inner surface of the bending region BR, side surfaces of the first and second backplate layers 610 and 620, and a side surface of the plate layer 800.

The housing HSP may be disposed at an outermost side of the display device 1. A portion extending in the thickness direction (or the third direction DR3) of the housing HSP may come into direct contact with the cover layer 300 and the mold MDP. A portion extending in the second direction DR2 of the housing HSP may be coupled to the mold MDP through the sixth bonding layer 760.

FIG. 6 is an enlarged cross-sectional view of area Q1 in FIG. 5. FIG. 6 illustrates the main region MR and the bending region BR of the display device 1 together. The bending region BR of FIG. 5 is a region having a curved shape, but for convenience of description, the flat bending region BR of FIG. 6 is illustrated.

Referring to FIGS. 4, 5, and 6, the panel inorganic layers 102, 103, 104, 105, 106, 108, and 109 may not be disposed in the bending region BR. Accordingly, the first protective layer 111 may come into direct contact with the substrate 101 in the bending region BR.

The link line LL may be disposed on the first protective layer 111. The link line LL may be a line connecting a pad (or a data pad) connected to the data driving unit DIC of FIG. 5 to a data line on the display area DA. The link line LL may be located on the same layer as the connection electrode 145 of FIG. 4, but the embodiments of the present specification are not limited thereto, and the link line LL may also be located on the same layer as the first source electrode 121.

The second protective layer 112 may be disposed on the link line LL. The second protective layer 112 may be disposed in the main region MR and the bending region BR.

Three dams D1, D2, and D3 may be disposed in the main region MR adjacent to the bending region BR. A first dam D1 may be disposed between the display region DA and the bending region BR, a second dam D2 may be disposed between the first dam D1 and a third dam D3, and the third dam D3 may be disposed between the second dam D2 and the bending region BR. The second protective layer 112 may form a first layer of the third dam D3.

The bank 154 may be disposed on the second protective layer 112. The bank 154 may be disposed on the main region MR and the bending region BR. In the main region MR, the bank 154 may form a first layer of the first dam D1, a first layer of the second dam D2, and a second layer of the third dam D3. In the third dam D3, the bank 154 that is a second layer may be disposed to completely cover the second protective layer 112 that is a first layer, but the embodiments of the present specification are not limited thereto.

The spacer 155 may be disposed on the bank 154. The spacer 155 may be disposed on the main region MR and the bending region BR. In the main region MR, the spacer 155 may form a second layer of the first dam D1, a second layer of the second dam D2, and a third layer of the third dam D3. In each of the second dam D2 and the third dam D3, the spacer 155 may have the same area as the bank 154, but the embodiments of the present specification are not limited thereto.

The encapsulation part 170 may be disposed on the spacer 155. The first encapsulation layer 171 may be disposed in the main region MR and may not be disposed in the bending region BR. The first encapsulation layer 171 may come into direct contact with the first dam D1, the second dam D2, and the third dam D3. The second encapsulation layer 172 may be ended by the first dam D1, and the third encapsulation layer 173 may be disposed in the main region MR but may not be disposed in the bending region BR. The third encapsulation layer 173 may come into direct contact with the first encapsulation layer 171 on the first dam D1.

A touch inorganic film may be disposed on the encapsulation part 170. The touch inorganic film may be disposed in the main region MR but may not be disposed in the bending region BR. The touch inorganic film may include the touch buffer layer 181 and the insulating layer 184.

A first touch organic layer 190 may be disposed on the insulating layer 184. The first touch organic layer 190 may be formed of an organic material containing an acrylic resin, an epoxy resin, a phenolic resin, a polyamide resin, or a polyimide resin, but the embodiments of the present specification are not limited thereto.

The first touch organic layer 190 may be disposed in the main region MR and may form a fourth dam D4 in the bending region BR. The fourth dam D4 may be disposed directly on the spacer 155 and may be spaced a predetermined distance from the boundary between the bending region BR and the main region MR, but the embodiments of the present specification are not limited thereto. The fourth dam D4 may be a touch organic layer dam. In the fourth dam D4, a second touch organic layer 195 may be ended. The second touch organic layer 195 may come into direct contact with a side surface of the fourth dam D4.

The second touch organic layer 195 may be disposed on the first touch organic layer 190. The second touch organic layer 195 may be formed of an organic material containing an acrylic resin, an epoxy resin, a phenolic resin, a polyamide resin, or a polyimide resin, but the embodiments of the present specification are not limited thereto.

The second touch organic layer 195 may come into direct contact with the side surface of the fourth dam D4, an upper surface of the spacer 155, and a side surface of the first touch organic layer 190 in the bending region BR.

The cover layer MCL may be disposed on the second touch organic layer 195. The cover layer MCL may be disposed on the bending region BR but may not be disposed on the main region MR. The cover layer MCL may come into direct contact with an upper surface and side surface of the fourth dam D4, an upper surface of the second touch organic layer 195, and the upper surface of the spacer 155.

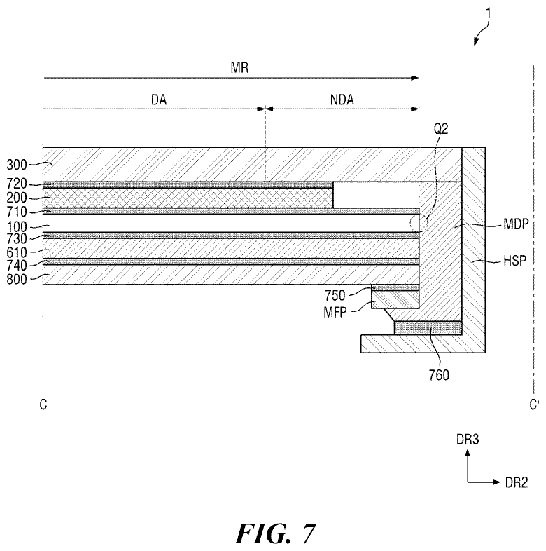

FIG. 7 is a cross-sectional view along line C-C′ in FIG. 3. FIG. 7 illustrates the main region MR including the display area DA and the non-display area NDA. FIG. 7 illustrates a cross-sectional view of a right region of the display device 1. The cross-sectional view of the right region of the display device 1 may be substantially the same as cross-sectional views of left and upper regions of the display device 1.

Referring to FIGS. 4 to 7, the mold MDP may come into direct contact with the side surface of the display panel 100, the side surface of the first backplate layer 610, and the side surface of the plate layer 800. The mold MDP may come into direct contact with the side surface and lower surface of the mold frame MFP. The mold MDP may be bonded to the housing HSP through the sixth bonding layer 760. The mold MDP may come into contact with the lower surface of the cover layer 300 and the inner surface of the housing HSP.

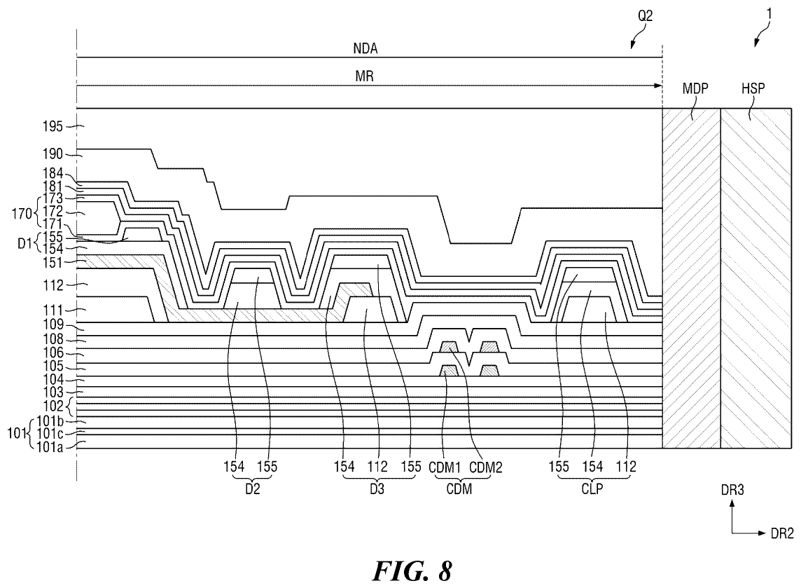

FIG. 8 is an enlarged cross-sectional view of area Q2 in FIG. 7.

Referring to FIGS. 4 to 8, the side surface of the display panel 100 may come into direct contact with the mold MDP, and the mold MDP may include an organic material that is greatly deformed (expands or shrinks) due to heat as described above. Accordingly, the side surface of the display panel 100 can be vulnerable to rigidity. Since the side surface of the display panel 100 is vulnerable to rigidity, film lifting or peeling between films may occur around the side surface of the display panel 100. In addition, since film lifting or peeling between films occurs around the side surface of the display panel 100, there is a very high possibility that cracks may occur around the side surface of the display panel 100.

When only the substrate 101 and the second touch organic layer 195 of the display panel 100 extend to the side surface of the display panel 100, the side surface of the display panel 100 can still be vulnerable to rigidity. The side surface of the display panel 100 may be a trimmed side surface.

In the case of the display device 1 according to one embodiment, at least one panel inorganic layer, the inorganic layers 171 and 173 of the encapsulation part 170, and at least one touch inorganic layer may be disposed on the side surface of the display panel 100. That is, a side surface of the buffer layer 102, a side surface of the first insulating layer 103, a side surface of the second insulating layer 104, a side surface of the third insulating layer 105, a side surface of the fourth insulating layer 106, a side surface of the fifth insulating layer 108, and a side surface of the sixth insulating layer 109 may each be aligned with a side surface of the substrate 101 and may come into direct contact with the mold MDP. In addition, the side surfaces of the first and second inorganic layers 171 and 173 may each be aligned with the side surface of the substrate 101 and may come into direct contact with the mold MDP. In addition, a side surface of the touch buffer layer 181 and a side surface of the insulating layer 184 may each be aligned with the side surface of the substrate 101 and may come into direct contact with the mold MDP. In the display panel 100 of the display device 1 according to one embodiment, since the side surface of the at least one panel inorganic layer, the side surfaces of the inorganic layers 171 and 173 of the encapsulation part 170, and the side surface of the at least one touch inorganic layer are disposed to be aligned with the side surface of the substrate 101, it is possible to secure the rigidity of the side surface of the display panel 100.

In addition, in the case of the display panel 100 according to one embodiment, the side surface of the first touch organic layer 190 may also be aligned with a side surface of the second touch organic layer 195, and the side surface of the first touch organic layer 190 may come into direct contact with the mold MDP. That is, since a step is not formed between the first touch organic layer 190 and the second touch organic layer 195 on the main region MR, it is possible to improve film lifting between the clad part CLP and the first touch organic layer 190 or between the first touch organic layer 190 and the second touch organic layer 195, or peeling between films.

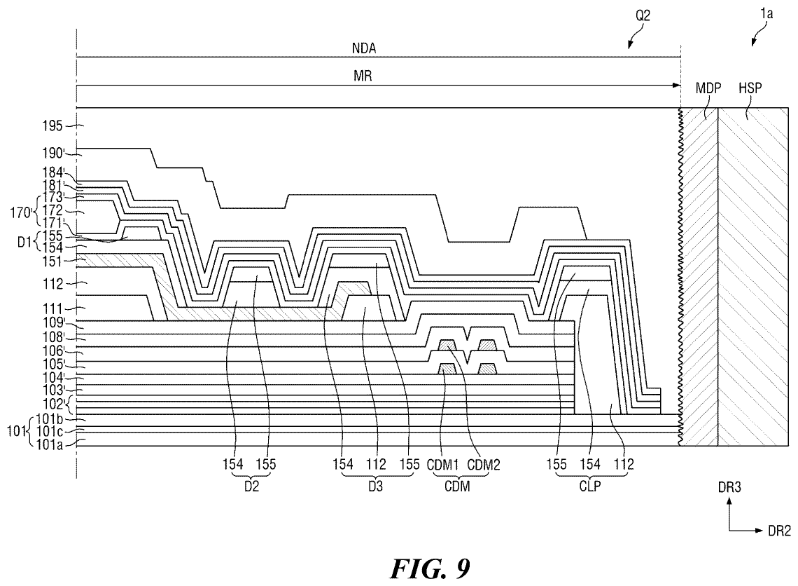

FIG. 9 is a cross-sectional view of a display device according to a comparative example.

Referring to FIGS. 8 and 9, in the case of a display device 1a according to a comparative example, side surfaces of one or more panel inorganic layers 102′, 103′, 104′, 105′, 106′, 108′, and 109′, side surfaces of inorganic layers 171′ and 173 of an encapsulation part 170′, and side surfaces of one or more touch inorganic layers 181′ and 184′ may be located inward of the side surface of the substrate 101. The side surfaces of the one or more panel inorganic layers 102′, 103′, 104′, 105′, 106′, 108′, and 109′ may be ended on the clad part CLP and may come into contact with the clad part CLP. The inorganic layers 171′ and 173′ of the encapsulation part 170′ and the one or more touch inorganic layers 181′ and 184′ may extend to the outside of the clad part CLP and may be ended inside the side surface of the substrate 101. In addition, a first touch organic layer 190′ may be ended on the clad part CLP. Accordingly, the second touch organic layer 195 may come into contact with a side surface of the first touch organic layer 190′ and cover the side surfaces of the inorganic layers 171′ and 173′ of the encapsulation part 170′ and the side surfaces of the one or more touch inorganic layers 181′ and 184′. As illustrated in FIG. 9, since the side surface of the substrate 101 and the side surface of the second touch organic layer 195 may come into direct contact with the mold MDP and the mold MDP is greatly deformed (expands or shrink) due to heat, the side surface of the display panel 100 (see FIG. 1) can be very vulnerable to rigidity.

However, as described above in FIG. 8, in the case of the display device 1 according to one embodiment, since the side surfaces of the one or more panel inorganic layers, the side surfaces of the inorganic layers 171 and 173 of the encapsulation part 170, and the side surfaces of the one or more touch inorganic layers are disposed to be aligned with the side surface of the substrate 101, it is possible to secure the rigidity of the side surface of the display panel 100.

In addition, in the case of the display panel 100 according to one embodiment, the side surface of the first touch organic layer 190 may also be aligned with the side surface of the second touch organic layer 195, and the side surface of the first touch organic layer 190 may come into direct contact with the mold MDP. That is, since a step is not formed between the first touch organic layer 190 and the second touch organic layer 195 on the main region MR, it is possible to improve film lifting between the clad part CLP and the first touch organic layer 190 or between the first touch organic layer 190 and the second touch organic layer 195, or peeling between films.

Hereinafter, a display device according to other embodiments will be described. In the following embodiments, detailed description of the reference numerals or components described in FIGS. 1 to 9 will be omitted, or overlapping description will be omitted.

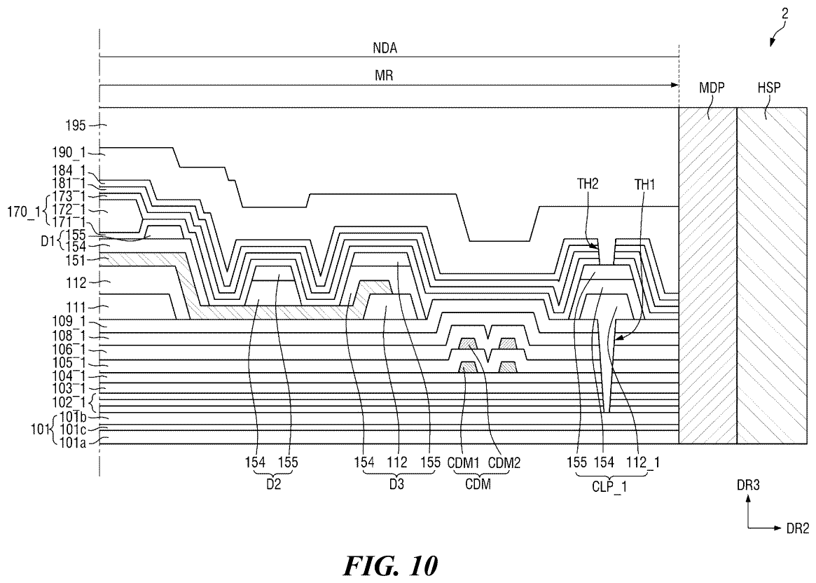

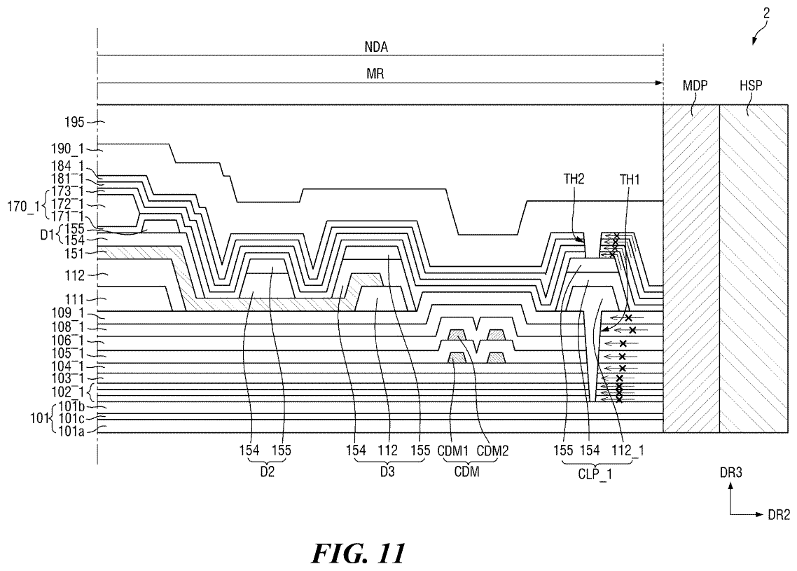

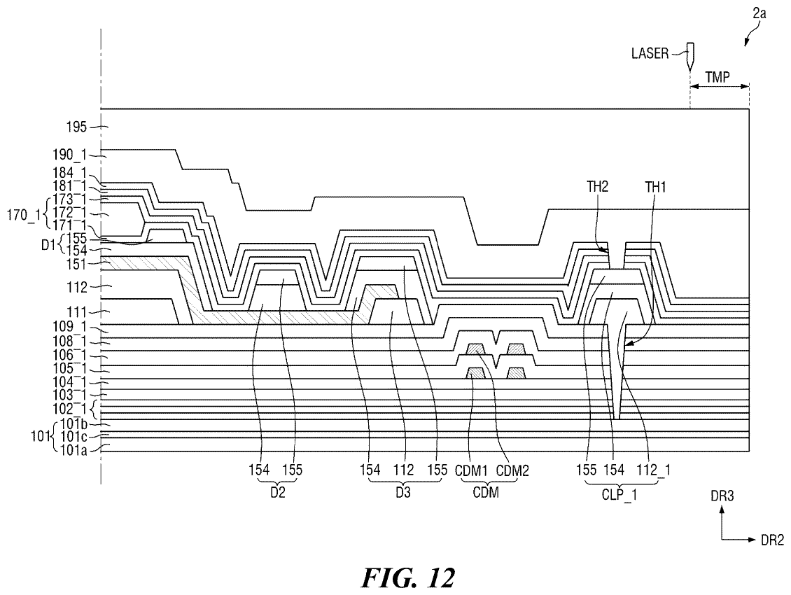

FIG. 10 is a cross-sectional view of a display device according to another embodiment. FIG. 11 is a schematic view illustrating cracks formed at an end portion of the display panel and blocked through a first stop hole and a second stop hole. FIG. 12 is a schematic view illustrating a process of removing a trimming part of the display device according to FIG. 10.

Referring to FIGS. 10 to 12, a display device 2 according to another embodiment differs from the display device 1 according to FIG. 8 in that it further includes first and second stop holes TH1 and TH2.

More specifically, the first stop hole TH1 may be formed in at least one panel inorganic layer, and the second stop hole TH2 may be formed in at least one touch inorganic layer and first and second inorganic layers 171_1 and 173_1 of an encapsulation part 170_1.

For example, the first stop hole TH1 may pass through a buffer layer 102_1, a first insulating layer 103_1, a second insulating layer 104_1, a third insulating layer 105_1, a fourth insulating layer 106_1, a fifth insulating layer 108_1, and a sixth insulating layer 109_1 in a thickness direction.

For example, the second stop hole TH2 may pass through an insulating layer 184_1, a touch buffer layer 181_1, a second inorganic layer 173_1, and a first inorganic layer 171_1 in the thickness direction.

In the first stop hole TH1, a clad part CLP_1 may come into direct contact with the substrate 101, and in the second stop hole TH2, a first touch organic layer 190_1 may come into direct contact with the clad part CLP_1. For example, a second protective layer 112_1 of the clad part CLP_1 may come into direct contact with the substrate 101, and the first touch organic layer 190_1 may come into direct contact with the spacer 155 of the clad part CLP_1.

The second substrate portion 101b of the substrate 101 may include an organic material, the clad part CLP_1 may include an organic material, and the first touch organic layer 190_1 may include an organic material. Accordingly, since the clad part CLP_1 comes into direct contact with the substrate 101 in the first stop hole TH1 and the first touch organic layer 190_1 comes into direct contact with the clad part CLP_1 in the second stop hole TH2, it is possible to reinforce bonding strength between films, thereby improving film lifting.

In addition, by trapping the residual film formed at end portions of the panel inorganic layer, the inorganic layers 171_1 and 173_1 of the encapsulation part 170_1, and the touch inorganic layer through the clad part CLP_1 and the first touch organic layer 190_1, it is possible to prevent a foreign substance defect and a dark spot defect.

In addition, the first stop hole TH1 and the second stop hole TH2 may perform a function of a stopper. Since the side surface of the display panel 100 (see FIG. 1) is vulnerable to rigidity, film lifting or peeling between films may occur around the side surface of the display panel 100. In addition, since film lifting or peeling between films occurs around the side surface of the display panel 100, there is a very high possibility that cracks may occur around the side surface of the display panel 100. The cracks may propagate to the inside of the display panel 100 through the inorganic layers disposed around the side surface of the display panel 100. However, as illustrated in FIG. 11, the cracks occurring around the side surface of the display panel 100 may be stopped by each of the first stop hole TH1 and the second stop hole TH2.

In addition, the clad part CLP_1 may be located outside the third dam D3. The clad part CLP_1 may be disposed between the side surface of the display panel 100 (see FIG. 1) and the third dam D3. That is, the clad part CLP_1 may be located at the outermost side of the display panel 100. By forming the first and second stop holes TH1 and TH2 on the clad part CLP located at the outermost side of the display panel 100, the cracks occurring on the side surface of the display panel 100 can be stopped at the outermost end of the display panel 100.

As illustrated in FIG. 12, a display panel of a display device 2a before cutting may further include a trimming area TMP. The trimming area TMP may be removed by a laser LASER. When the trimming area TMP is removed, the side surface of the display panel of the display device 2 of FIG. 11 is exposed. Even during the process of removing the trimming area TMP, there is a high possibility that cracks may occur on the side surface of the display panel. However, according to the display device 2 of another embodiment, by forming the first and second stop holes TH1 and TH2 on the clad part CLP located at the outermost side of the display panel 100 (see FIG. 1), the cracks occurring on the side surface of the display panel 100 can be stopped at the outermost end of the display panel 100.

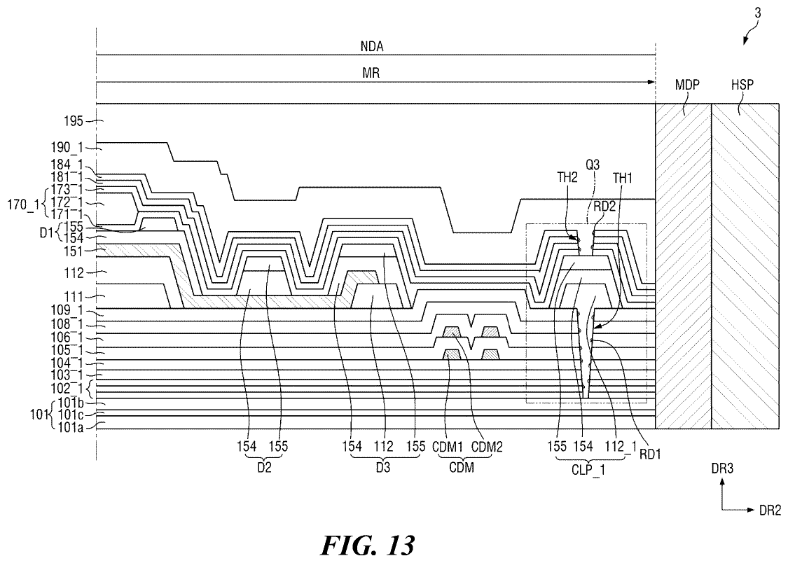

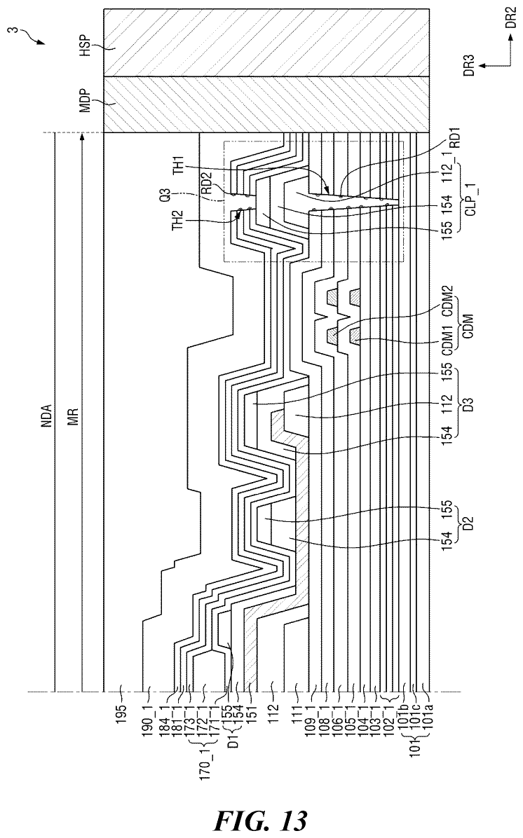

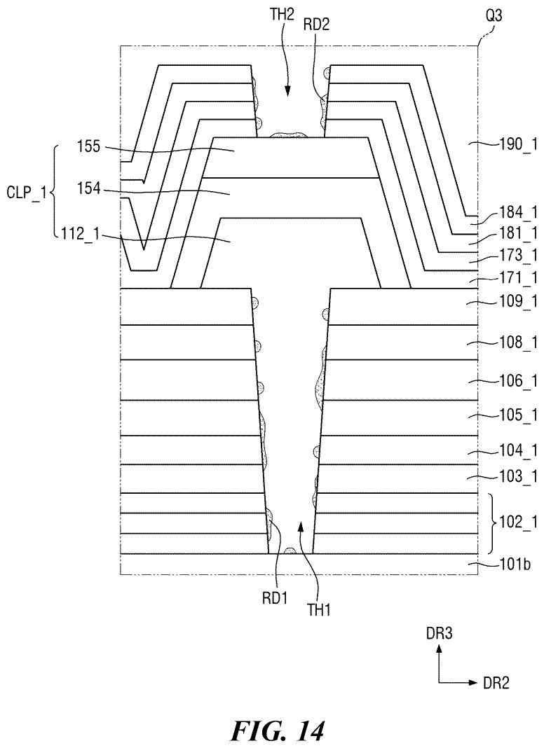

FIG. 13 is a cross-sectional view of a display device according to still another embodiment. FIG. 14 is an enlarged cross-sectional view of area Q3 in FIG. 13.

Referring to FIGS. 13 and 14, a display panel of a display device 3 according to still another embodiment differs from the display device 2 according to FIG. 10 in that a first residual film RD1 may be formed on inner surfaces of one or more panel inorganic layers 102_1, 103_1, 104_1, 105_1, 106_1, 108_1, and 109_1 in the first stop hole TH1 and a second residual film RD2 may be formed on inner surfaces of inorganic layers 171_1 and 173_1 or one or more touch inorganic layers 181_1 and 184_1 in the second stop hole TH2.

More specifically, the first residual film RD1 and the second residual film RD2 may be trapped by the clad part CLP_1 inside the first stop hole TH1 and the first touch organic layer 190_1 inside the second stop hole TH2, respectively.

The first residual film RD1 may be disposed between the clad part CLP_1 inside the first stop hole TH1 and the inner surfaces of the one or more panel inorganic layers 102_1, 103_1, 104_1, 105_1, 106_1, 108_1, and 109_1, and the second residual film RD2 may be disposed between the first touch organic layer 190_1 inside the second stop hole TH2 and the inner surfaces of the inorganic layers 171_1 and 173_1 or the one or more touch inorganic layers 181_1 and 184_1. The first residual film RD1 may be further disposed between an upper surface of the second substrate portion 101b and the clad part CLP_1, and the second residual film RD2 may be further disposed between the first touch organic layer 190_1 and the clad part CLP_1, but the embodiments of the present specification are not limited thereto.

The first residual film RD1 may be formed, for example, during the process of forming the first gate electrode 122 of FIG. 4, the process of forming the second light-shielding layer 136, or the process of forming the first source electrode 121, and the second residual film RD2 may be formed, for example, during the process of forming the cathode electrode 153 of FIG. 4, the process of forming the second touch electrode 182, or the process of forming the first touch electrode 185. That is, the first residual film RD1 may include the same material as the first gate electrode 122, the second light-shielding layer 136, or the first source electrode 121, and the second residual film RD2 may include the same material as the cathode electrode 153 or the second touch electrode 182.

When the first residual film RD1 or the second residual film RD2 is exposed and remains on end portions of the one or more panel inorganic layers 102_1, 103_1, 104_1, 105_1, 106_1, 108_1, and 109_1, end portions of the one or more inorganic layers 171_1 and 173_1, or end portions of the one or more touch inorganic layers 181_1 and 184_1, the first residual film RD1 or the second residual film RD2 may move inside the display panel 100 (see FIG. 1) to cause a foreign substance defect or a dark spot defect.

However, in the case of the display device 3 according to the present embodiment, the first residual film RD1 and the second residual film RD2 may be trapped by the clad part CLP_1 inside the first stop hole TH1 and the first touch organic layer 190_1 inside the second stop hole TH2, respectively. Accordingly, it is possible to prevent a foreign substance defect or a dark spot defect.

A display device according to embodiments of the present specification includes a display panel including a display area including a pixel and a non-display area located around the display area, and a mold disposed on a side surface of the display panel, in which the display panel includes a substrate, at least one panel inorganic layer on the substrate, a light-emitting part on the at least one panel inorganic layer, a touch part including at least one touch inorganic layer on the light-emitting part and a touch electrode on the at least one touch inorganic layer, and a first touch organic layer on the touch part, and the substrate, the at least one panel inorganic layer, and the first touch organic layer come into direct contact with the mold.

According to the display device according to the embodiments of the present specification, a side surface of the substrate, a side surface of the at least one panel inorganic layer, a side surface of the at least one touch inorganic layer, and a side surface of the first touch organic layer may be aligned.

The display device according to the embodiments of the present specification may further include a second touch organic layer on the first touch organic layer, in which the second touch organic layer may come into direct contact with the mold, and a side surface of the second touch organic layer may be aligned with a side surface of the first touch organic layer.

According to the display device according to the embodiments of the present specification, the display panel may include a main region, a sub-region overlapping the main region, and a bending region between the main region and the sub-region, and the bending region may have a curved shape.

The display device according to the embodiments of the present specification may further include a mold frame under the display panel, and the mold may come into direct contact with a side surface and a lower surface of the mold frame.

The display device according to the embodiments of the present specification may further include a backplate layer between the display panel and the mold frame, and a plate layer between the backplate layer and the mold frame, and the mold on the bending region may come into direct contact with the backplate layer and the plate layer.

The display device according to the embodiments of the present specification may further include a cover layer on the bending region of the display panel, and the cover layer may come into direct contact with the mold.

According to the display device according to the embodiments of the present specification, the at least one panel inorganic layer and the at least one touch inorganic layer may not be disposed in the bending region, the first touch organic layer may include a touch organic layer dam located in the bending region, and the second touch organic layer may be ended at the touch organic layer dam.

The display device according to the embodiments of the present specification may further include a clad part located in the non-display area of the main region, and a dam between the clad part and the display area.

The display device according to the embodiments of the present specification may further include a first protective layer between the at least one panel inorganic layer and the light-emitting part, a second protective layer between the first protective layer and the light-emitting part, a bank on an anode electrode of the light-emitting part, and a spacer between the bank and the touch part, in which the clad part and the dam may each be formed of at least one of the first protective layer, the second protective layer, the bank, and the spacer.

According to the display device according to the embodiments of the present specification, the clad part may include the second protective layer, the bank, and the spacer.

According to the display device according to the embodiments of the present specification, the at least one panel inorganic layer may include a first stop hole that overlaps the clad part and passes therethrough in a thickness direction of the display panel.

According to the display device according to the embodiments of the present specification, the clad part may fill the first stop hole and come into direct contact with the substrate.

The display device according to the embodiments of the present specification may further include a first residual film between the side surface of the at least one panel inorganic layer and the clad part, in which the first residual film may include a metal.

According to the display device according to the embodiments of the present specification, the at least one touch inorganic layer may include a second stop hole that overlaps the clad part and passes therethrough in the thickness direction of the display panel.

According to the display device according to the embodiments of the present specification, the first touch organic layer may fill the second stop hole and come into direct contact with the clad part.

The display device according to the embodiments of the present specification may further include a second residual film between the at least one panel inorganic layer and the first touch organic layer, in which the second residual film may include a metal.

A display device according to embodiments of the present specification includes a substrate including a display area including a pixel and a non-display area located around the display area, at least one panel inorganic layer on the substrate, a protective layer on the at least one panel inorganic layer, a light-emitting part including an anode electrode on the protective layer, an organic layer on the anode electrode, and a cathode electrode on the organic layer, a bank covering an edge of the anode electrode and disposed between the anode electrode and the organic layer, and a clad part including a spacer between the bank and the organic layer, located in the non-display area, and formed of the protective layer, the bank, or the spacer, in which the at least one panel inorganic layer includes a first stop hole that overlaps the clad part and passes through in a thickness direction, and the clad part fills the first stop hole and comes into direct contact with the substrate.

The display device according to the embodiments of the present specification may further include a touch part including at least one touch inorganic layer on the light-emitting part and a touch electrode on the at least one touch inorganic layer, and a first touch organic layer on the touch part, in which the at least one touch inorganic layer may include a second stop hole that overlaps the clad part and passes therethrough in the thickness direction, and the first touch organic layer may fill the second stop hole and come into direct contact with the clad part.

The display device according to the embodiments of the present specification may further include a dam disposed between the clad part and the display area, in which the dam may be formed of the protective layer, the bank, or the spacer.

According to the display device of the embodiments, it is possible to secure the rigidity of the trim line (the edge) of the display panel by arranging at least one panel inorganic layer and at least one touch inorganic layer to be aligned with the side surfaces of the substrate, respectively.

In addition, according to the display device of the embodiments, it is possible to remove the organic film step on the clad part by arranging the first touch organic layer to be aligned with the side surface of the substrate and the side surface of the second touch organic layer thereon. Accordingly, it is possible to improve the film lifting between the clad part and the first touch organic layer or the first touch organic layer and the second touch organic layer or peeling between films.

In addition, the display device according to the embodiments can include the clad part disposed around the left, right, or upper end portion of the display panel, the at least one panel inorganic layer can include the first stop hole passing therethrough in the thickness direction, and the at least one touch inorganic layer can include the second stop hole passing therethrough in the thickness direction. The clad part can come into contact with the substrate through the first stop hole, and the first touch organic layer can come into contact with the clad part through the second stop hole. The clad part, the substrate, and the first touch organic layer can each include an organic material. Accordingly, the display device according to the embodiments can improve film lifting by reinforcing bonding strength between films on the clad part.

In addition, according to the display device of the embodiments, the first stop hole and the second stop hole can be formed in the clad part located at the outermost side of the display panel. Accordingly, it is not necessary to separately form the stop hole inside the clad part (or in the non-display area between the clad part and the display area), it is possible to implement the narrow bezel.

In addition, according to the display device of the embodiments, by forming the first stop hole and the second stop hole in the clad part located at the outermost side of the display panel, it is possible to block cracks of the end portion of the display panel, which is caused by an external force, at the outermost end of the display panel.

In addition, according to the display device of the embodiments, it is possible to prevent a foreign substance defect and a dark spot defect by trapping the residual film formed at the end portions of the panel inorganic layer and the touch inorganic layer through the clad part and the first touch organic layer.

In addition, according to the display device of the embodiments, by blocking cracks of the end portion of the display panel at the outermost end of the display panel through the first stop hole and the second stop hole, it is possible to prevent moisture from penetrating the display area through the cracks, thereby extending the life of the display device.

However, effects obtainable from the present specification are not limited to the above-described effects, and other effects that are not mentioned will be able to be clearly understood by those skilled in the art to which the present specification pertains from the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1, 2, 3: display device
100: display panel
CLP: clad part
D1, D1, D2, D4: dam

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including:
a display area including a pixel; and
a non-display area located around the display area; and
a mold on a side surface of the display panel,
wherein the display panel includes:
a substrate;
at least one panel inorganic layer on the substrate;
a light-emitting part on the at least one panel inorganic layer;
a touch part including at least one touch inorganic layer on the light-emitting part and a touch electrode on the at least one touch inorganic layer; and
a first touch organic layer on the touch part, and
the substrate, the at least one panel inorganic layer, and the first touch organic layer come into contact with the mold.

2. The display device of claim 1, wherein a side surface of the substrate, a side surface of the at least one panel inorganic layer, a side surface of the at least one touch inorganic layer, and a side surface of the first touch organic layer are aligned.

3. The display device of claim 2, further comprising a second touch organic layer on the first touch organic layer, wherein the second touch organic layer comes into direct contact with the mold, and a side surface of the second touch organic layer is aligned with a side surface of the first touch organic layer.

4. The display device of claim 3, wherein the display panel includes a main region, a sub-region overlapping the main region, and a bending region between the main region and the sub-region, and the bending region has a curved shape.

5. The display device of claim 4, further comprising a mold frame under the display panel, wherein the mold comes into direct contact with a side surface and a lower surface of the mold frame.

6. The display device of claim 5, further comprising a backplate layer between the display panel and the mold frame, and a plate layer between the backplate layer and the mold frame, wherein the mold on the bending region comes into direct contact with the backplate layer and the plate layer.

7. The display device of claim 4, further comprising a cover layer on the bending region of the display panel, wherein the cover layer comes into direct contact with the mold.

8. The display device of claim 4, wherein the at least one panel inorganic layer and the at least one touch inorganic layer are not disposed in the bending region, the first touch organic layer includes a touch organic layer dam located in the bending region, and the second touch organic layer is ended at the touch organic layer dam.

9. The display device of claim 4, further comprising a clad part located in the non-display area of the main region, and a dam between the clad part and the display area.

10. The display device of claim 9, further comprising a first protective layer between the at least one panel inorganic layer and the light-emitting part, a second protective layer between the first protective layer and the light-emitting part, a bank on an anode electrode of the light-emitting part, and a spacer between the bank and the touch part, wherein the clad part and the dam are each formed of at least one of the first protective layer, the second protective layer, the bank, and the spacer.

11. The display device of claim 10, wherein the clad part includes the second protective layer, the bank, and the spacer.

12. The display device of claim 11, wherein the at least one panel inorganic layer includes a first stop hole that overlaps the clad part and passes therethrough in a thickness direction of the display panel.

13. The display device of claim 12, wherein the clad part fills the first stop hole and comes into direct contact with the substrate.

14. The display device of claim 13, further comprising a first residual film between the side surface of the at least one panel inorganic layer and the clad part, wherein the first residual film includes a metal.

15. The display device of claim 11, wherein the at least one touch inorganic layer includes a second stop hole that overlaps the clad part and passes therethrough in a thickness direction of the display panel.

16. The display device of claim 15, wherein the first touch organic layer fills the second stop hole and comes into direct contact with the clad part.

17. The display device of claim 16, further comprising a second residual film between the at least one panel inorganic layer and the first touch organic layer, wherein the second residual film includes a metal.

18. The display device of claim 1, wherein side surfaces of the at least one panel inorganic layer, the at least one touch inorganic layer, and the first touch organic layer are substantially flush with a side surface of the substrate.

19. The display device of claim 2, wherein a side surface of the at least one touch inorganic layer comes into direct contact with the mold.

20. A display device comprising:
a display panel including:
a display area including a pixel; and
a non-display area located around the display area;
at least one panel inorganic layer on a substrate of the display panel;
a protective layer on the at least one panel inorganic layer;
a light-emitting part including an anode electrode on the protective layer, an organic layer on the anode electrode, and a cathode electrode on the organic layer;
a bank that covers an edge of the anode electrode and disposed between the anode electrode and the organic layer; and
a spacer between the bank and the organic layer,
wherein a clad part located in the non-display area and formed of the protective layer, the bank, or the spacer is included,
the at least one panel inorganic layer includes a first stop hole that overlaps the clad part and passes therethrough in a thickness direction of the display panel, and
the clad part is present in the first stop hole and comes into direct contact with the substrate.

21. The display device of claim 20, further comprising a touch part including at least one touch inorganic layer on the light-emitting part and a touch electrode on the at least one touch inorganic layer, and a first touch organic layer on the touch part, wherein the at least one touch inorganic layer includes a second stop hole that overlaps the clad part and passes therethrough in the thickness direction, and the first touch organic layer fills the second stop hole and comes into direct contact with the clad part.

22. The display device of claim 21, further comprising a dam between the clad part and the display area, wherein the dam is formed of the protective layer, the bank, or the spacer.
